(19) United States
(12) Patent Application Publication
(10) Pub. No.: US 2013/0327374 A1
(43) Pub. Date: Dec. 12, 2013

(54) PHOTOELECTRIC CONVERSION DEVICE AND PHOTOELECTRIC CONVERSION DEVICE MODULE

(71) Applicants: Ryoichi Komiya, Osaka-shi (JP); Atsushi Fukui, Osaka-shi (JP); Ryosuke Yamanaka, Osaka-shi (JP)

(72) Inventors: Ryoichi Komiya, Osaka-shi (JP); Atsushi Fukui, Osaka-shi (JP); Ryosuke Yamanaka, Osaka-shi (JP)

(73) Assignee: SHARP KABUSHIKI KAISHA, Osaka-shi, Osaka (JP)

(21) Appl. No.: 14/000,669

(22) PCT Filed: Feb. 27, 2012
(86) PCT No.: PCT/JP2012/054720

§ 371 Date: Aug. 21, 2013

(30) Foreign Application Priority Data
Feb. 28, 2011 (JP) 2011-041264

(51) Int. Cl. H01L 31/02

(52) U.S. Cl. CPC H01L 31/02021
USPC 136/251; 136/256

(57) ABSTRACT

A photoelectric conversion device according to the present invention includes a transparent or translucent substrate and a supporting substrate both fixed in place with a sealant. The photoelectric conversion device further includes a transparent electrically conductive layer disposed on the transparent or translucent substrate, a photoelectric conversion layer disposed on the transparent electrically conductive layer a counter electrically conductive layer in contact with or separated from the supporting substrate, a terminal electrode on the photoelectric conversion layer side electrically connected to the transparent electrically conductive layer, and a counter terminal electrode electrically connected to the counter electrically conductive layer. The transparent electrically conductive layer, the photoelectric conversion layer, and the counter electrically conductive layer contain a carrier transport material.

### TECHNICAL FIELD

The present invention relates to a photoelectric conversion device and a photoelectric conversion device module.

### BACKGROUND ART

Solar batteries for converting sunlight into electric power are receiving attention as energy sources to replace fossil fuels. Solar batteries that include a crystalline silicon substrate and thin-film silicon solar batteries are practically used. However, the solar batteries have a problem in that the cost of manufacturing the silicon substrate is high. The thin-film silicon solar batteries also have a problem of high manufacturing costs because of the use of a wide variety of semiconductor manufacturing gases and complicated apparatuses. Although there have been efforts to improve photoelectric conversion efficiency to reduce the cost per unit output for both types of solar battery, these problems have not yet been solved.

A photoelectric conversion device that utilizes photoinduced electron transfer of a metal complex is proposed as a new type of solar battery (for example, Patent Literature 1 (Japanese Patent No. 2664194 (Japanese Unexamined Patent Application Publication No. 1-220380))). This photoelectric conversion device has a structure in which a photoelectric conversion layer and an electrolyte solution are disposed between two glass substrates. The photoelectric conversion layer has an absorption spectrum in a visible light region due to a photosensitizing dye adsorbed thereon. A first electrode and a second electrode are disposed on the two glass substrates.

Light irradiation on the first electrode side generates electrons in the photoelectric conversion layer. The electrons move from the first electrode to the opposite second electrode through an external electrical circuit. The electrons are then carried back to the photoelectric conversion layer by electrolyte ions. Such sequential electron movement can produce electrical energy.

The photoelectric conversion device described in Patent Literature 1 contains the electrolyte solution between the electrodes disposed on the two glass substrates. Thus, although a small-area solar battery can be test-manufactured using the technique described in Patent Literature 1, a large-area solar battery, for example, of 1 m square is difficult to manufacture using the technique described in Patent Literature 1. More specifically, an increase in the area of one solar battery cell results in an increase in generated current in proportion to the area of the solar battery cell but results in an increase in the resistance of the first electrode in the in-plane direction and consequently an increase in the internal series resistance of the solar battery. This results in a decrease in fill factor (FF) among the current-voltage characteristics during photoelectric conversion.

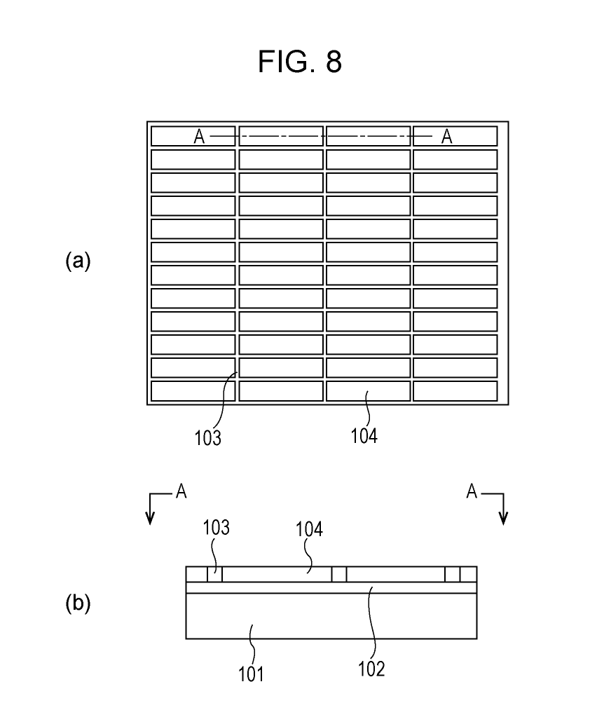

In order to prevent such a decrease in FF, Patent Literature 2 (Japanese Unexamined Patent Application Publication No. 2003-203681) proposes a dye-sensitized solar cell that includes collecting electrodes 103 on a first electrode 102. FIG. 8(a) is a top view of a dye-sensitized solar cell described in Patent Literature 2. FIG. 8(b) is a cross-sectional view taken along the line A-A in FIG. 8(a).

As illustrated in FIG. 8(b), the dye-sensitized solar cell described in Patent Literature 2 includes strips of photoelectric conversion layers 104 in the same plane on the first electrode 102. The collecting electrodes 103 made of a gold-silver alloy are disposed in a grid pattern between the photoelectric conversion layers 104. The collecting electrodes 103 can reduce electrical resistance, dramatically improve FF, and improve short-circuit current density.

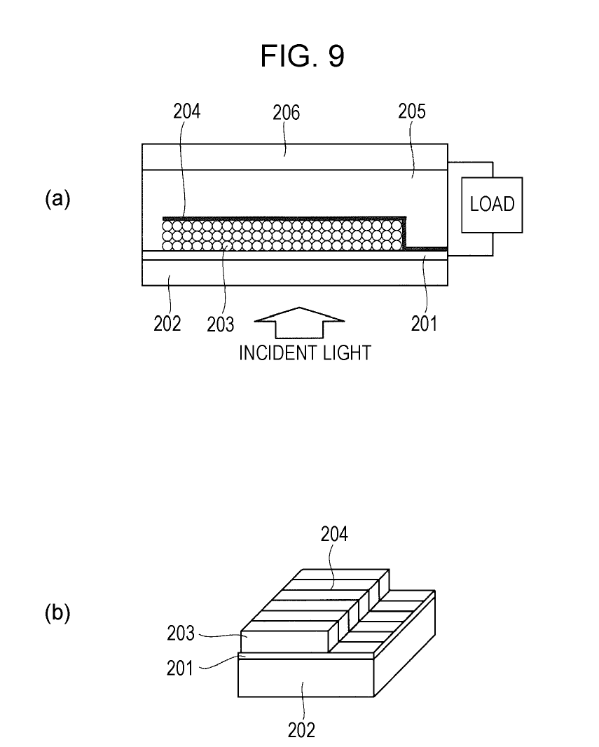

Apart from Patent Literature 2, in order to prevent a decrease in FF, Patent Literature 3 (Japanese Patent No. 4474691 (Japanese Unexamined Patent Application Publication No. 2000-243465)) proposes a dye-sensitized solar cell illustrated in FIGS. 9(a) and 9(b). FIG. 9(a) is a schematic cross-sectional view of a dye-sensitized solar cell described in Patent Literature 3. FIG. 9(b) is a schematic view of another dye-sensitized solar cell described in Patent Literature 3.

As illustrated in FIG. 9(a), a dye-sensitized solar cell described in Patent Literature 3 includes photoelectric conversion layers 203 on a first electrode 201 and a collecting electrode 204 on the photoelectric conversion layers 203 (on the surfaces of the photoelectric conversion layers 203 opposite the first electrode 201). As illustrated in FIG. 9(b), Patent Literature 3 proposes another dye-sensitized solar cell that includes collecting electrodes 204 arranged in lines or in a grid-like fashion so as not to block the movement of an electrolyte. The collecting electrodes 204 are formed on 5-cm squares of photoelectric conversion layers 203 to dramatically improve FF and improve short-circuit current density.

### CITATION LIST

Patent Literature

PTL 1: Japanese Patent No. 2664194 (Japanese Unexamined Patent Application Publication No. 1-220380)

PTL 2: Japanese Unexamined Patent Application Publication No. 2003-203681

PTL 3: Japanese Patent No. 4474691 (Japanese Unexamined Patent Application Publication No. 2000-243465)

### SUMMARY OF INVENTION

Technical Problem

Even when the shape of the collecting electrode is changed as described in Patent Literature 2, however, FF has an upper limit in the range of approximately 0.66 to 0.67 and could not be further improved. Depending on the material of the collecting electrode 204 in the dye-sensitized solar cell described in Patent Literature 3, the collecting electrode 204 may have a high leakage current. Thus, the dye-sensitized solar cell described in Patent Literature 3 may have the problems of a low open-circuit voltage and resulting low conversion efficiency.

Depending on the thickness of the photoelectric conversion layer 203 in the dye-sensitized solar cell described in Patent Literature 3, there may be little installation effect of the collecting electrode 204. The following is the reason for this problem. Light irradiation causes electron distribution in the thickness direction of the photoelectric conversion layer 203 and narrows the electron distribution from the light-receiving surface in the thickness direction. Installation of the collecting electrode 204 on a portion having a narrow electron distribution can rarely produce the effects of current collection.

In view of the situations described above, it is an object of the present invention to provide a photoelectric conversion device and a photoelectric conversion device module that can effectively improve FF, short-circuit current, and open-circuit voltage.

Solution to Problem

As a result of extensive studies to solve the problems described above, the present inventors completed the present invention by finding that FF is improved by forming a terminal electrode at each end of a photoelectric conversion layer in the longitudinal direction in a photoelectric conversion device and a photoelectric conversion device module.

A photoelectric conversion device according to the present invention includes a transparent or translucent substrate and a supporting substrate both fixed in place with a sealant. The photoelectric conversion device further includes a transparent electrically conductive layer disposed on the transparent or translucent substrate, a photoelectric conversion layer disposed on the transparent electrically conductive layer, a counter electrically conductive layer in contact with or separated from the supporting substrate, a terminal electrode on the photoelectric conversion layer side electrically connected to the transparent electrically conductive layer, and a counter terminal electrode electrically connected to the counter electrically conductive layer. The transparent electrically conductive layer, the photoelectric conversion layer, and the counter electrically conductive layer contain a carrier transport material.

The terminal electrode on the photoelectric conversion layer side preferably has a sheet resistance equal to or lower than the sheet resistance of the transparent electrically conductive layer.

The counter terminal electrode preferably has a sheet resistance equal to or lower than the sheet resistance of the counter electrically conductive layer.

The photoelectric conversion layer preferably has a width of 6 mm or less and a length of 5 cm or less.

The terminal electrode on the photoelectric conversion layer side or the counter terminal electrode preferably contains at least one metallic material selected from titanium, nickel, tungsten, and tantalum.

A photoelectric conversion device according to the present invention module includes two or more photoelectric conversion devices electrically connected in series, wherein at least one of the photoelectric conversion devices is the photoelectric conversion device described above. A photoelectric conversion device according to the present invention module includes the photoelectric conversion devices described above connected in series.

### ADVANTAGEOUS EFFECTS OF INVENTION

The present invention can provide a photoelectric conversion device and a photoelectric conversion device module that can effectively improve FF, short-circuit current, and open-circuit voltage and consequently have high conversion efficiency.

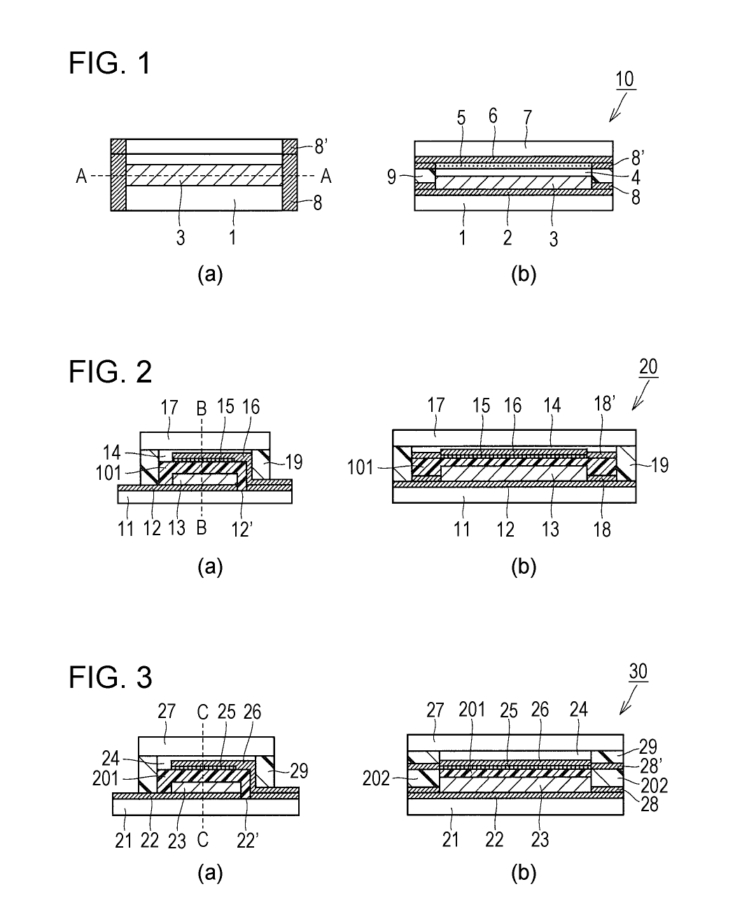

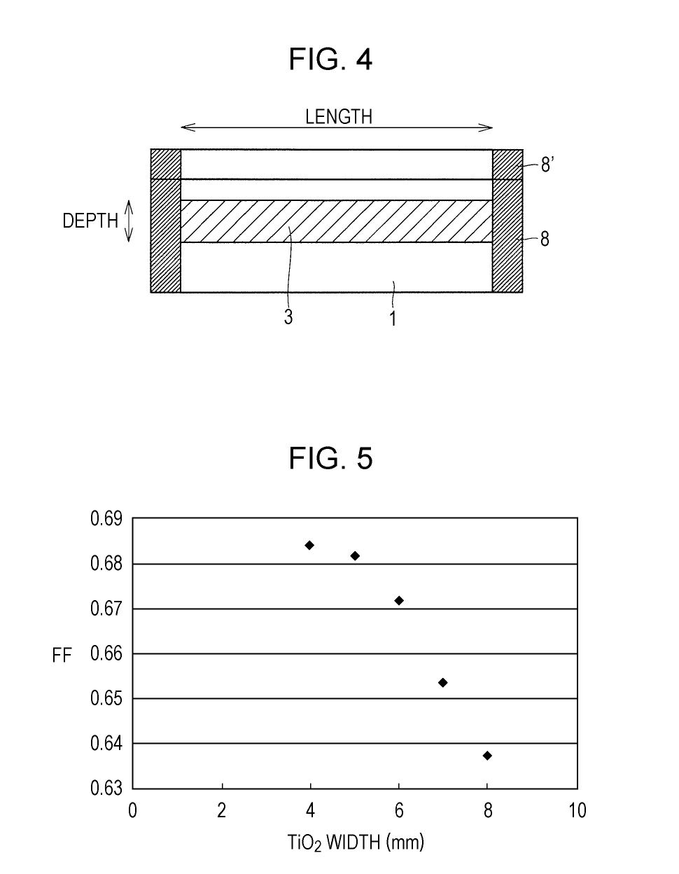

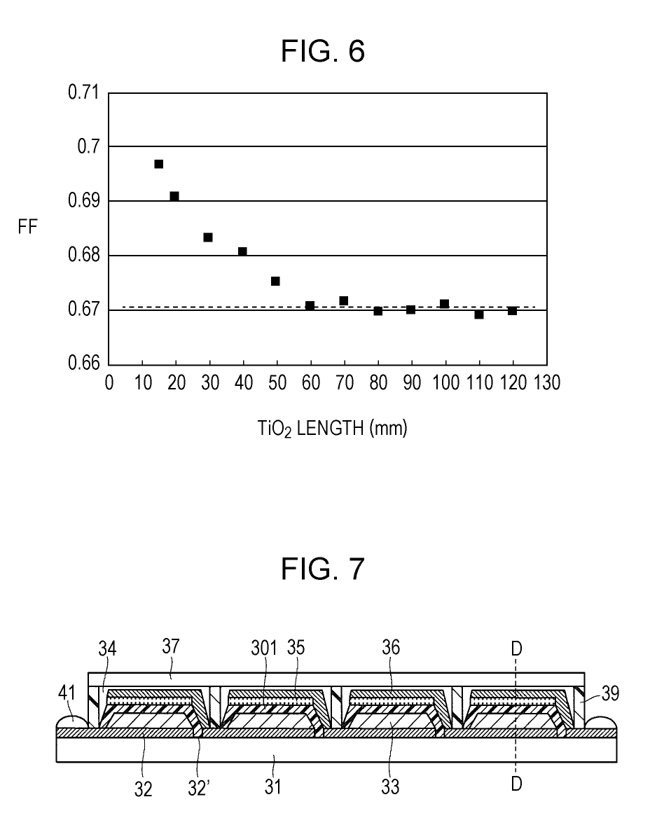

### BRIEF DESCRIPTION OF DRAWINGS

[FIG. 1] FIG. 1(a) is a top view of a photoelectric conversion device according to the present invention, and FIG. 1(b) is a cross-sectional view taken along the line A-A in FIG. 1(a).

[FIG. 2] FIG. 2(a) is a cross-sectional view of a photoelectric conversion device according to the present invention, and FIG. 2(b) is a cross-sectional view taken along the line B-B in FIG. 2(a).

[FIG. 3] FIG. 3(a) is a cross-sectional view of a photoelectric conversion device according to the present invention, and FIG. 3(b) is a cross-sectional view taken along the line C-C in FIG. 3(a).

[FIG. 4] FIG. 4 is a top view of a photoelectric conversion device according to the present invention.

[FIG. 5] FIG. 5 is a graph of FF as a function of the width of a photoelectric conversion layer according to the present invention.

[FIG. 6] FIG. 6 is a graph of FF as a function of the length of a photoelectric conversion layer according to the present invention.

[FIG. 7] FIG. 7 is a schematic cross-sectional view of the structure of a photoelectric conversion device module according to an embodiment of the present invention.

[FIG. 8] FIG. 8(a) is a top view of a dye-sensitized solar cell module described in Patent Literature 2, and FIG. 8(b) is a cross-sectional view taken along the line A-A in FIG. 8(a).

[FIG. 9] FIG. 9(a) is a schematic cross-sectional view of a dye-sensitized solar cell described in Patent Literature 3, and FIG. 9(b) is a schematic cross-sectional view of another dye-sensitized solar cell described in Patent Literature 3.

### DESCRIPTION OF EMBODIMENTS

A photoelectric conversion device and a photoelectric conversion device module according to the present invention will be described below with reference to the accompanying drawings. Like reference numerals designate like parts throughout these drawings of the present invention. For the sake of clarity and simplification, the dimensions, such as length, width, thickness, and depth, in the drawings are appropriately modified and are not actual dimensions.

<Photoelectric Conversion Device>

Photoelectric conversion devices according to first to third embodiments of the present invention will be described below with reference to FIGS. 1 to 3.

### FIRST EMBODIMENT

FIG. 1(a) is a schematic top view of the structure of a photoelectric conversion device according to an embodiment of the present invention, and FIG. 1(b) is a cross-sectional view taken along the line A-A in FIG. 1(a). As illustrated in FIG. 1(a), a photoelectric conversion device 10 according to the present embodiment includes a terminal electrode 8 on the photoelectric conversion layer side and a counter terminal electrode 8′ at each end of a transparent or translucent substrate 1 in the longitudinal direction so as not to cover a photoelectric conversion layer 3.

The photoelectric conversion device 10 according to the present embodiment is further characterized by the following. As illustrated in FIG. 1(b), the photoelectric conversion device 10 according to the present embodiment includes the transparent or translucent substrate 1 and a supporting substrate 7 both fixed in place with a sealant 9. The photoelectric conversion device 10 further includes a transparent electrically conductive layer 2 disposed on the transparent or translucent substrate 1, the photoelectric conversion layer 3 disposed on the transparent electrically conductive layer 2, a counter electrically conductive layer 6 in contact with or separated from the supporting substrate 7, the terminal electrode 8 on the photoelectric conversion layer side electrically connected to the transparent electrically conductive layer 2, and the counter terminal electrode 8′ electrically connected to the counter electrically conductive layer 6. The transparent electrically conductive layer 2, the photoelectric conversion layer 3, and the counter electrically conductive layer 6 contain a carrier transport material.

The photoelectric conversion layer 3 is a porous semiconductor layer on which a photosensitizer is adsorbed. A catalyst layer 5 is disposed on the undersurface of the counter electrically conductive layer 6. A space between the photoelectric conversion layer 3 and the catalyst layer 5 is filled with a carrier transport material 4. The components of the photoelectric conversion device 10 according to the present embodiment will be described below.

<<Transparent or Translucent Substrate>>

In the present invention, at least a light-receiving surface of the transparent or translucent substrate 1 must be optically transparent and must be made of an optically transparent material. The optically transparent material of the transparent or translucent substrate 1 is only required to be substantially transparent to light having a wavelength at which the light has effective sensitivity to a dye described below and is not necessarily transparent to light in the entire wavelength range. The transparent or translucent substrate 1 preferably has a thickness in the range of approximately 0.2 to 5 mm.

The material of the transparent or translucent substrate 1 may be any material that is generally used in solar batteries. The transparent or translucent substrate 1 may be a glass substrate, for example, made of soda-lime glass, fused silica glass, or crystal quartz glass, or a heat-resistant resin sheet, such as a flexible film. The material of the flexible film may be tetraacetylcellulose (TAC), poly(ethylene terephthalate) (PET), poly(phenylene sulfide) (PPS), polycarbonate (PC), polyarylate (PA), polyetherimide (PEI), a phenoxy resin, or Teflon (registered trademark).

When another member is formed on the transparent or translucent substrate 1 by heating, for example, when the photoelectric conversion layer 3 of the porous semiconductor layer is formed on the transparent or translucent substrate 1 by heating at approximately 250° C., the transparent or translucent substrate 1 is particularly preferably made of Teflon (registered trademark) having heat resistance of 250° C. or more. The transparent or translucent substrate 1 can be utilized as a base for installation on another structure. The periphery of the transparent or translucent substrate 1 can be easily attached to another structure using a machined metal part and screws.

<<Transparent Electrically Conductive Layer>>

In the present invention, the material of the transparent electrically conductive layer 2 is only required to be substantially transparent to light having a wavelength at which the light has effective sensitivity to a photosensitizer described below and is not necessarily transparent to light in the entire wavelength range. Examples of such a material include indium tin oxide (ITO), tin oxide (SnO₂), fluorine-doped tin oxide (FTO), zinc oxide (ZnO), and tantalum- or niobium-doped titanium oxide.

The transparent electrically conductive layer 2 may be formed on the transparent or translucent substrate 1 by a known method, such as sputtering or spraying. The transparent electrically conductive layer 2 preferably has a thickness in the range of approximately 0.02 to 5 μm. The transparent electrically conductive layer 2 preferably has a film resistance as low as possible, more preferably 40 ohms per square or less.

For the transparent or translucent substrate 1 made of soda-lime float glass, the transparent electrically conductive layer 2 made of FTO is particularly preferably disposed on the transparent or translucent substrate 1. A commercially available transparent or translucent substrate including a transparent electrically conductive layer may be used.

<<Photoelectric Conversion Layer>>

In the present invention, the photoelectric conversion layer 3 is a porous semiconductor layer on which a photosensitizer is adsorbed. The carrier transport material 4 can move inside and outside the photoelectric conversion layer 3. FIG. 4 is a schematic top view of the structure of a photoelectric conversion device according to an embodiment of the present invention. In a photoelectric conversion device according to the present invention as illustrated in FIG. 4, the photoelectric conversion layer 3 preferably has a width (“depth” in FIG. 4) of 6 mm or less. The width direction of the photoelectric conversion layer 3 is perpendicular to the longitudinal direction of the photoelectric conversion layer 3. The longitudinal direction of the photoelectric conversion layer 3 is a direction from one terminal electrode 8 on the photoelectric conversion layer side to the other terminal electrode 8 on the photoelectric conversion layer side. FIG. 5 is a graph of the fill factor (FF) as a function of the width of the photoelectric conversion layer 3 made of titanium oxide. As is clear from the result of the graph shown in FIG. 5, when the photoelectric conversion layer 3 has a width of more than 6 mm, the photoelectric conversion device has a reduced fill factor. Thus, the photoelectric conversion layer 3 preferably has a width of 6 mm or less.

The photoelectric conversion layer 3 preferably has a length of 5 cm or less. FIG. 6 is a graph of the fill factor (FF) as a function of the length of the photoelectric conversion layer 3 made of titanium oxide. As is clear from the result of the graph shown in FIG. 6, when the photoelectric conversion layer 3 has a length of more than 5 cm, the photoelectric conversion device has a reduced fill factor. Thus, the photoelectric conversion layer 3 preferably has a length of 5 cm or less.

The reason that the photoelectric conversion device has a reduced fill factor when the photoelectric conversion layer 3 has a length of more than 5 cm is that the terminal electrode 8 on the photoelectric conversion layer side and the counter terminal electrode 8′ have a reduced effect of improving the fill factor when the photoelectric conversion layer 3 has a length of more than 5 cm. The reason that the photoelectric conversion device has a reduced fill factor when the photoelectric conversion layer 3 has a width of more than 6 mm is that when the photoelectric conversion layer 3 has a width of more than 6 mm the transparent electrically conductive layer 2 has increased resistance and the terminal electrode 8 on the photoelectric conversion layer side and the counter terminal electrode 8′ have a reduced effect of improving the fill factor. The porous semiconductor layer and the photosensitizer will be described below.

(Porous Semiconductor Layer)

The porous semiconductor layer may be made of any common photoelectric conversion material. Examples of such a material include semiconductor compound materials, such as titanium oxide, zinc oxide, tin oxide, iron oxide, niobium oxide, cerium oxide, tungsten oxide, barium titanate, strontium titanate, cadmium sulfide, lead sulfide, zinc sulfide, indium phosphide, copper-indium sulfide (CuInS₂), CuAlO₂, and SrCu₂O₂. These materials may be used alone or in combination. Among these semiconductor compound materials, titanium oxide is particularly preferred in terms of stability and safety.

Examples of titanium oxide that can be suitably used in the porous semiconductor layer include various narrowly-defined titanium oxides, such as anatase titanium dioxide, rutile titanium dioxide, amorphous titanium oxide, metatitanic acid, and orthotitanic acid, as well as titanium hydroxide and hydrous titanium oxide. These titanium oxides that can be suitably used in the porous semiconductor layer may be used alone or in combination. Anatase titanium dioxide and rutile titanium dioxide are interchangeable depending on the production method or thermal history. The porous semiconductor layer preferably has a high anatase titanium dioxide content and more preferably has an anatase titanium dioxide content of 80% or more.

The porous semiconductor layer may be composed of single crystals or various crystals and is preferably composed of various crystals in terms of stability, ease of crystal growth, and manufacturing costs. The porous semiconductor layer is preferably composed of semiconductor fine particles of a nanometer to micrometer size and is more preferably composed of titanium oxide fine particles. Such titanium oxide fine particles can be produced by a known method, such as a gas phase method or a liquid phase method (a hydrothermal synthesis method or a sulfuric acid method), or a high-temperature hydrolysis method using chloride developed by Degussa AG.

The semiconductor fine particles of the porous semiconductor layer may be composed of a semiconductor compound material or two or more different semiconductor compound materials. The semiconductor fine particles may have an average particle size in the range of approximately 100 to 500 nm or approximately 5 to 50 nm. The semiconductor fine particles having these average particle sizes may be mixed. Semiconductor fine particles having an average particle size in the range of approximately 100 to 500 nm can scatter incident light and improve light interception. Semiconductor fine particles having an average particle size in the range of approximately 5 to 50 nm have a larger number of adsorption sites and can contribute to an increase in the amount of adsorbed dye.

In the case that the porous semiconductor layer is composed of two or more semiconductor fine particles having different average particle sizes, the larger average particle size is preferably at least 10 times the smaller average particle size. In a mixture of two or more semiconductor fine particles having different average particle sizes, it is effective to produce the semiconductor fine particles having a smaller average particle size from a semiconductor material having higher adsorption.

The thickness of the porous semiconductor layer, that is, the thickness of the photoelectric conversion layer 3 is not particularly limited and is preferably the same as the height of an insulating member between cells (an insulating member between the electrodes of the photoelectric conversion device), for example, approximately in the range of 0.1 to 100 μm. The porous semiconductor layer preferably has a large surface area, for example, in the range of approximately 10 to 200 m²/g.

(Photosensitizer)

The photosensitizer adsorbed on the porous semiconductor layer converts the energy of light entering the photoelectric conversion device into electrical energy. In order for the photosensitizer to be strongly adsorbed on the porous semiconductor layer, the photosensitizer preferably has an interlock group, such as a carboxy group, an alkoxy group, a hydroxy group, a sulfo group, an ester group, a mercapto group, or a phosphoryl group in its molecule. The interlock group is generally located between the porous semiconductor layer and a dye fixed onto the porous semiconductor layer and produces electrical coupling that facilitates electron transfer between an excited dye and a conduction band of the semiconductor material constituting the porous semiconductor layer.

Examples of the photosensitizer to be adsorbed on the porous semiconductor layer include various organic dyes having absorption in a visible light region or an infrared light region and metal complex dyes. These dyes may be used alone or in combination.

Examples of the organic dyes include azo dyes, quinone dyes, quinonimine dyes, quinacridone dyes, squarylium dyes, cyanine dyes, merocyanine dyes, triphenylmethane dyes, xanthene dyes, porphyrin dyes, perylene dyes, indigo dyes, and naphthalocyanine dyes. In general, such organic dyes have a higher absorption coefficient than metal complex dyes described below.

The metal complex dyes contain a transition metal coordinately bonded to a metal atom. Examples of such metal complex dyes include porphyrin dyes, phthalocyanine dyes, naphthalocyanine dyes, and ruthenium dyes. Examples of the metal atom of the metal complex dyes include Cu, Ni, Fe, Co, V, Sn, Si, Ti, Ge, Cr, Zn, Ru, Mg, Al, Pb, Mn, In, Mo, Y, Zr, Nb, Sb, La, W, Pt, Ta, Ir, Pd, Os, Ga, Tb, Eu, Rb, Bi, Se, As, Sc, Ag, Cd, Hf, Re, Au, Ac, Tc, Te, and Rh. Among others, the metal complex dyes are preferably phthalocyanine or ruthenium dyes to which a metal is coordinately bonded, particularly preferably ruthenium metal complex dyes.

The metal complex dyes are particularly preferably ruthenium metal complex dyes represented by the following formulae (1) to (3). Examples of the commercially available ruthenium metal complex dyes include Ruthenium 535 dye, Ruthenium 535-bisTBA dye, and Ruthenium 620-1H3TBA dye (trade names) manufactured by Solaronix.

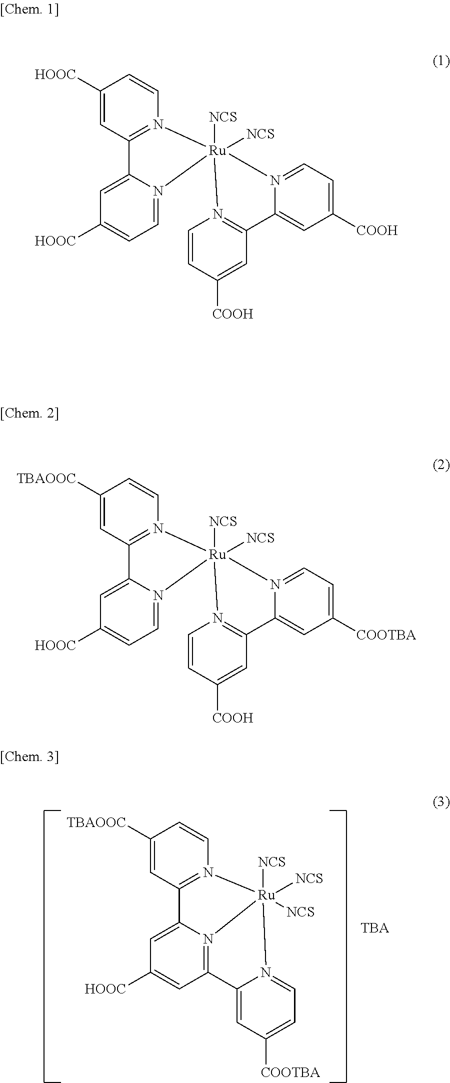

<<Carrier Transport Material>>

In the photoelectric conversion device illustrated in FIG. 1 in the present invention, the carrier transport material 4 is charged in a region surrounded by the transparent electrically conductive layer 2, the counter electrically conductive layer 6, and the sealant 9 and is also charged in the photoelectric conversion layer 3 and the catalyst layer 5.

A photoelectric conversion device according to the present invention is not limited to that illustrated in FIG. 1 and may have a structure illustrated in FIG. 2 or 3. As in the photoelectric conversion device illustrated in FIG. 1, in the photoelectric conversion device illustrated in FIG. 2, a carrier transport material is charged in a region surrounded by a transparent electrically conductive layer 12, a supporting substrate 17, and a sealant 19 and is also charged in a photoelectric conversion layer 13, a catalyst layer 15, and a porous insulating layer 101. In the present specification, for convenience, a region filled with a carrier transport material alone without other constituents is a carrier transport material 14. The structures of the photoelectric conversion devices illustrated in FIGS. 2 and 3 will be described later.

Such a carrier transport material is composed of an electrically conductive material that can transport ions. A liquid electrolyte, a solid electrolyte, a gel electrolyte, or a molten salt gel electrolyte may be used as a suitable material.

The liquid electrolyte may be a liquid substance containing a redox species and may be any liquid electrolyte generally used in the field of solar batteries. For example, the liquid electrolyte may contain a redox species and a solvent that can dissolve the redox species, a redox species and a molten salt that can dissolve the redox species, or a redox species and a solvent and a molten salt that can dissolve the redox species.

Examples of the redox species include an I⁻/I³⁻ system, a Br²⁻/Br³⁻ system, an Fe²⁺/Fe³⁺ system, and a quinone/hydroquinone system. More specifically, the redox species is preferably a combination of iodine (I₂) and a metal iodide, such as lithium iodide (LiI), sodium iodide (NaI), potassium iodide (KI), or calcium iodide (CaI₂), a combination of iodine and a tetraalkylammonium salt, such as tetraethylammonium iodide (TEAI), tetrapropylammonium iodide (TPAI), tetrabutylammonium iodide (TBAI), or tetrahexylammonium iodide (THAI), or a combination of bromine and a metal bromide, such as lithium bromide (LiBr), sodium bromide (NaBr), potassium bromide (KBr), or calcium bromide (CaBr₂). Among these, the redox species is particularly preferably a combination of LiI and I₂.

Examples of the solvent for redox species include carbonate compounds, such as propylene carbonate, nitrile compounds, such as acetonitrile, alcohols, such as ethanol, water, and aprotic polar substances. Among these, the solvent for redox species is particularly preferably a carbonate compound or a nitrile compound. The solvent for redox species may be a mixture of at least two of these solvents.

Preferably, the solid electrolyte is an electrically conductive material that can transport electrons, holes, or ions, can be used as an electrolyte for photoelectric conversion devices, and is not a fluid. More specifically, examples of the solid electrolyte include hole transport materials, such as polycarbazole, electron transport materials, such as tetranitrofloorurenone, electrically conductive polymers, such as polyrol, and polyelectrolytes, which are liquid electrolytes solidified with high-molecular compounds. The solid electrolyte may be a liquid electrolyte containing a p-type semiconductor material, such as copper iodide or copper thiocyanate, or a molten salt solidified with fine particles.

The gel electrolyte is generally composed of an electrolyte and a gelling agent. Examples of the gelling agent include polymer gelling agents, such as cross-linked polyacrylic resin derivatives, cross-linked polyacrylonitrile derivatives, poly(alkylene oxide) derivatives, silicone resins, and polymers having a nitrogen-containing heterocyclic quaternary compound salt structure in their side chains.

The molten salt gel electrolyte is generally composed of a gel electrolyte as described above and a room temperature molten salt. Examples of the room temperature molten salt include nitrogen-containing heterocyclic quaternary ammonium salt compounds, such as pyridinium salts and imidazolium salts.

If necessary, an additive agent may be added to the electrolyte. Examples of the additive agent include nitrogen-containing aromatic compounds, such as t-butylpyridine (TBP), and imidazole salts, such as dimethylpropylimidazole iodide (DMPII), methylpropylimidazole iodide (MPII), ethylmethylimidazole iodide (EMII), ethylimidazole iodide (EII), and hexylmethylimidazole iodide (HMII).

The electrolyte concentration is preferably 0.001 mol/L or more and 1.5 mol/L or less, more preferably 0.01 mol/L or more and 0.7 mol/L or less. In the case that the supporting substrate 7 has a light-receiving surface in a dye-sensitized solar cell module, incident light reaches the photoelectric conversion layer 3 through an electrolyte solution to excite carriers. This may impair the performance of the photoelectric conversion device at some electrolyte concentration. Thus, the electrolyte concentration is preferably determined with this performance degradation taken into account.

<<Sealant>>

In the present invention, the sealant 9 joins the transparent or translucent substrate 1 and the supporting substrate 7 together. The sealant 9 is preferably composed of a silicone resin, an epoxy resin, a polyisobutylene resin, a hot-melt resin, or a glass material or may have a multilayer structure of two or more of these materials.

For example, the material of the sealant 9 is a product number 31X-101 manufactured by ThreeBond Co., Ltd., a product number 31X-088 manufactured by ThreeBond Co., Ltd., or a commercially available epoxy resin. When the sealant 9 is formed using a silicone resin, an epoxy resin, or a glass frit, the sealant 9 is preferably formed with a dispenser. When the sealant 9 is formed using a hot-melt resin, a hot-melt resin sheet may be cut in a certain pattern.

<<Terminal Electrode on Photoelectric Conversion Layer Side>>

In the present invention, the terminal electrode 8 on the photoelectric conversion layer side is electrically connected to the photoelectric conversion layer 3 and is disposed in contact with the transparent electrically conductive layer 2 and the sealant 9 between the transparent electrically conductive layer 2 and the sealant 9. More specifically, the terminal electrode 8 on the photoelectric conversion layer side is disposed on a portion of the transparent electrically conductive layer 2 not covered with the photoelectric conversion layer 3 and is disposed at each end of the transparent or translucent substrate 1 in the longitudinal direction. The terminal electrode 8 on the photoelectric conversion layer side can reduce the internal resistance of the photoelectric conversion device.

The material of the terminal electrode 8 on the photoelectric conversion layer side may be any electrically conductive material and may be optically transparent or not. In the case that a light-receiving surface is disposed on the photoelectric conversion layer 3 side, the material is preferably optically transparent. The material of the terminal electrode 8 on the photoelectric conversion layer side may be indium tin oxide (ITO), tin oxide (SnO₂), fluorine-doped tin oxide (FTO), or zinc oxide (ZnO), or a metal that is resistant to corrosion in the electrolyte solution, such as titanium, nickel, tungsten, or tantalum. The terminal electrode 8 on the photoelectric conversion layer side made of such a material can be formed by a known method, such as sputtering or spraying. The terminal electrode 8 on the photoelectric conversion layer side may be formed simultaneously with the transparent electrically conductive layer 2 or may be formed before or after the formation of the transparent electrically conductive layer 2.

The terminal electrode 8 on the photoelectric conversion layer side preferably has a thickness in the range of approximately 0.02 to 5 μm and film resistance as small as possible. The terminal electrode 8 on the photoelectric conversion layer side preferably has a sheet resistance equal to or lower than the sheet resistance of the transparent electrically conductive layer 2. The sheet resistance may be measured with a sheet resistance measuring apparatus or may be measured by a four-probe method or a four-terminal method. This can reduce the internal resistance of the photoelectric conversion device. In the case that the terminal electrode 8 on the photoelectric conversion layer side is formed on a surface of the transparent electrically conductive layer 2, the sheet resistance of the terminal electrode 8 on the photoelectric conversion layer side formed on the surface of the transparent electrically conductive layer 2 may be the sheet resistance of the terminal electrode 8 on the photoelectric conversion layer side.

<<Counter Terminal Electrode>>

In the present invention, the counter terminal electrode 8′ is electrically connected to the counter electrically conductive layer 6 and is disposed in contact with the counter electrically conductive layer 6 and the sealant 9 between the counter electrically conductive layer 6 and the sealant 9. More specifically, the counter terminal electrode 8′ is disposed on a portion of the undersurface of the counter electrically conductive layer 6 not overlapping with the photoelectric conversion layer 3 and is disposed at each end of the transparent or translucent substrate 1 in the longitudinal direction. The counter terminal electrode 8′ can reduce the internal resistance of the photoelectric conversion device.

The composition, structure, and formation method of the counter terminal electrode 8′ may be the same as the composition, structure, and formation method of the terminal electrode 8 on the photoelectric conversion layer side. The counter terminal electrode 8′ preferably has a sheet resistance equal to or lower than the sheet resistance of the counter electrically conductive layer 6. The sheet resistance is measured by the method described above. This can make the effect of improving the fill factor with the counter terminal electrode 8′ effective. In the case that the counter terminal electrode 8′ is formed on a surface of the counter electrically conductive layer 6, the sheet resistance of the counter terminal electrode 8′ formed on the surface of the counter electrically conductive layer 6 may be the sheet resistance of the counter terminal electrode 8′.

<<Supporting Substrate>>

In the present invention, the supporting substrate 7 preferably contains the carrier transport material 4 and prevents the entry of water. In the case that the supporting substrate 7 has a light-receiving surface, the supporting substrate 7 must be optically transparent as in the transparent or translucent substrate 1. Thus, the supporting substrate 7 is preferably made of the same material as the transparent or translucent substrate 1. Considering that the photoelectric conversion device is installed in the outdoors, the supporting substrate 7 is preferably made of tempered glass.

The supporting substrate 7 (in the presence of a catalyst layer or/and a counter electrically conductive layer on a surface of the supporting substrate 7, the term “supporting substrate 7”, as used herein, includes the catalyst layer or/and the counter electrically conductive layer) is preferably separated from the photoelectric conversion layer 3 disposed on the transparent or translucent substrate 1. This allows a sufficient amount of carrier transport material to be contained in the photoelectric conversion device. The supporting substrate 7 preferably has an inlet for injecting the carrier transport material. The carrier transport material can be injected through the inlet by vacuum injection or vacuum impregnation. Since the supporting substrate 7 is separated from the photoelectric conversion layer 3 disposed on the transparent or translucent substrate 1, the injection rate of the carrier transport material through the inlet can be increased. This can reduce the manufacturing tact time of the photoelectric conversion device and the photoelectric conversion device module.

<<Counter Electrically Conductive Layer>>

In the present invention, the material of the counter electrically conductive layer 6 may be any electrically conductive material and does not necessarily require optical transparency. In the case that the supporting substrate 7 has a light-receiving surface, the material of the counter electrically conductive layer 6 is preferably optically transparent as in the transparent electrically conductive layer 2.

The material of the counter electrically conductive layer 6 may be indium tin oxide (ITO), tin oxide (SnO₂), fluorine-doped tin oxide (FTO), or zinc oxide (ZnO), or a metal that is resistant to corrosion in the electrolyte solution, such as titanium, nickel, or tantalum. The counter electrically conductive layer 6 made of such a material can be formed by a known method, such as sputtering or spraying.

The counter electrically conductive layer 6 preferably has a thickness in the range of approximately 0.02 to 5 μm. The counter electrically conductive layer 6 preferably has a film resistance as low as possible, preferably 40 ohms per square or less.

<<Catalyst Layer>>

In the present invention, the catalyst layer 5 is preferably in contact with the counter electrically conductive layer 6. The material of the catalyst layer 5 may be any material that can give and receive electrons on the surface of the catalyst layer 5, for example, a noble metal material, such as platinum or palladium, or a carbon material, such as carbon black, ketjen black, carbon nanotube, or fullerene.

### SECOND EMBODIMENT

FIG. 2(a) is a schematic cross-sectional view of the structure of a photoelectric conversion device according to an embodiment of the present invention, and FIG. 2(b) is a cross-sectional view taken along the line B-B in FIG. 2(a). A photoelectric conversion device according to the present invention may have the structure illustrated in FIGS. 2(a) and 2(b).

As illustrated in FIG. 2(b), in a photoelectric conversion device according to the present embodiment, a transparent or translucent substrate 11 and a supporting substrate 17 are fixed in place with a sealant 19. The photoelectric conversion device includes a transparent electrically conductive layer 12 disposed on the transparent or translucent substrate 11 and a photoelectric conversion layer 13 disposed on the transparent electrically conductive layer 12.

The transparent electrically conductive layer 12 has a scribe line 12′. A porous insulating layer 101 is disposed on the scribe line 12′ and the photoelectric conversion layer 13. A catalyst layer 15 and a counter electrically conductive layer 16 are disposed on the porous insulating layer 101. The supporting substrate 17 is fixed to the transparent or translucent substrate 11 with the sealant 19. A region surrounded by the supporting substrate 17, the sealant 19, and the transparent or translucent substrate 11 is filled with a carrier transport material 14. Empty spaces of the photoelectric conversion layer 13, the porous insulating layer 101, and the catalyst layer 15 are also filled with the carrier transport material 14.

A photoelectric conversion device 20 according to the present embodiment includes a terminal electrode 18 on the photoelectric conversion layer side between the sealant 19 and the photoelectric conversion layer 13 and a counter terminal electrode 18′ between the sealant 19 and the counter electrically conductive layer 16. The components in the present embodiment may be the same as in the first embodiment. Thus, the porous insulating layer 101 will be described below.

<<Porous Insulating Layer>>

In the present invention, the porous insulating layer 101 is provided in order to reduce the leakage current from the photoelectric conversion layer 13 to the counter electrically conductive layer 16. The material of the porous insulating layer 101 may be niobium oxide, zirconium oxide, silicon oxide, such as silica glass or soda-lime glass, aluminum oxide, or barium titanate. These materials may be selectively used alone or in combination. The material for the porous insulating layer 101 is preferably particles. The particles for use in the porous insulating layer 101 more preferably have an average particle size in the range of 5 to 500 nm, still more preferably 10 to 300 nm. The material of the porous insulating layer 101 is preferably titanium oxide or rutile titanium dioxide particles having an average size in the range of 100 to 500 nm.

<<Counter Electrically Conductive Layer>>

In the present embodiment, the material and structure of the counter electrically conductive layer 16 may be the same as those of the counter electrically conductive layer in the first embodiment. The counter electrically conductive layer 16 preferably has a plurality of small pores so that the carrier transport material can easily pass through the counter electrically conductive layer 16.

Such small pores can be formed by physical contact with or laser machining of the counter electrically conductive layer 16. The small pores preferably have a size in the range of approximately 0.1 to 100 μm, more preferably approximately 1 to 50 μm. The distance between the small pores is preferably in the range of approximately 1 to 200 μm, more preferably approximately 10 to 300 μm. The counter electrically conductive layer 16 having openings in a striped pattern also has substantially the same effects. The openings in the striped pattern are preferably disposed at intervals in the range of approximately 1 to 200 μm, more preferably approximately 10 to 300 μm.

### THIRD EMBODIMENT

FIG. 3(a) is a schematic cross-sectional view of the structure of a photoelectric conversion device according to an embodiment of the present invention, and FIG. 3(b) is a cross-sectional view taken along the line C-C in FIG. 3(a). A photoelectric conversion device according to the present invention may have the structure illustrated in FIG. 3. Being different from the photoelectric conversion device according to the second embodiment, the photoelectric conversion device illustrated in FIG. 3 includes an insulating layer 202 between a terminal electrode 28 on the photoelectric conversion layer side and a counter terminal electrode 28′.

A photoelectric conversion device 30 according to the present embodiment includes a transparent or translucent substrate 21, a transparent electrically conductive layer 22 disposed on the transparent or translucent substrate 21, a photoelectric conversion layer 23 disposed on the transparent electrically conductive layer 22, a porous insulating layer 201 disposed on the photoelectric conversion layer 23, a catalyst layer 25 disposed on the porous insulating layer 201, and a counter electrically conductive layer 26 disposed on the catalyst layer 25.

The transparent electrically conductive layer 22 disposed on the transparent or translucent substrate 21 is fixed to the terminal electrode 28 on the photoelectric conversion layer side with a sealant (not shown). A supporting substrate 27 is fixed to the counter terminal electrode 28′ with a sealant 29. A region surrounded by the supporting substrate 27, the sealant 29, and the transparent or translucent substrate 21 is filled with a carrier transport material 24. Empty spaces of the photoelectric conversion layer 23, the porous insulating layer 201, and the catalyst layer 25 are also filled with the carrier transport material 24. The components in the present embodiment may be the same as in the first and second embodiments. Thus, the insulating layer 202 will be described below.

<<Insulating Layer>>

The insulating layer 202 in the present embodiment is provided between the terminal electrode 28 on the photoelectric conversion layer side and the counter terminal electrode 28′ in order to insulate the terminal electrode 28 on the photoelectric conversion layer side from the counter terminal electrode 28′.

The material of the insulating layer 202 may be any material that can electrically insulate the terminal electrode 28 on the photoelectric conversion layer side from the counter terminal electrode 28′ and is preferably a material that makes the inner structure of the insulating layer 202 dense. Examples of the material of the insulating layer 202 include silicone resins, epoxy resins, polyisobutylene resins, hot-melt resins, and glass materials. The insulating layer 202 may have a multilayer structure composed of a plurality of layers made of at least two of these materials.

In the case that the insulating layer 202 is formed before the formation of the porous semiconductor layer, the insulating layer 202 must be resistant to heat at a heating temperature during the formation of the porous semiconductor layer. In the case that the transparent or translucent substrate 1 has a light-receiving surface, the insulating layer 202 is also irradiated with ultraviolet light and must therefore be resistant to ultraviolet light. From such a point of view, the material of the insulating layer 202 is preferably a glass material, more preferably a bismuth glass paste.

Some of the glass materials are commercially available as glass pastes or glass frits, for example. Considering reactivity with the carrier transport material and environmental issues, lead-free glass materials are preferred. In the case that the insulating layer 202 is formed on the transparent or translucent substrate 1 made of a glass material, the insulating layer 202 is preferably formed at a baking temperature of 550° C. or less. A method for manufacturing each component will be described below.

<<Method for Forming Porous Semiconductor>>

The porous semiconductor layer of the photoelectric conversion layer 23 is formed on the transparent or translucent substrate 21. The porous semiconductor layer may be formed by any method and may be formed by a known method. For example, a suspension of semiconductor fine particles dispersed in an appropriate solvent is applied to a predetermined portion by a known method, such as a doctor blade method, a squeegee method, a spin coating method, or a screen printing method, and is subjected to at least one of drying and baking to form the porous semiconductor layer.

In the case that the photoelectric conversion layer 23 is formed in a region defined by the sealant 29, preferably, the viscosity of the suspension is reduced, and the suspension having the reduced viscosity is applied to the region (the region defined by the sealant 29) with a dispenser. The suspension spreads to the ends of the region owing to its own weight and is easily leveled off.

Examples of the solvent of the suspension include glyme solvents, such as ethylene glycol monomethyl ether, alcohols, such as isopropyl alcohol, alcohol mixed solvents, such as isopropyl alcohol/toluene, and water. Instead of the suspension, a commercially available titanium oxide paste (for example, Ti-nanoxide, T, D, T/SP, or D/SP, manufactured by Solaronix) may be used.

The suspension thus prepared is applied to the transparent electrically conductive layer 2 and is subjected to at least one of drying and baking to form the porous semiconductor layer on the transparent electrically conductive layer 2. The suspension can be applied by a known method, such as a doctor blade method, a squeegee method, a spin coating method, or a screen printing method.

The conditions (such as temperature, time, and atmosphere) for the drying and baking of the suspension depend on the type of semiconductor fine particles. For example, the suspension is preferably dried and baked in the atmosphere or in an inert gas atmosphere, and the suspension is preferably dried and baked at a temperature in the range of approximately 50° C. to 800° C. for approximately 10 seconds to 12 hours. The suspension may be dried and baked once at a fixed temperature or twice or more at different temperatures.

The porous semiconductor layer may be a multilayer. The porous semiconductor multilayer is preferably formed by preparing different suspensions of semiconductor fine particles and performing at least one of application, drying, and baking twice or more.

After the porous semiconductor layer is formed in this manner, in order to improve electrical connection between the semiconductor fine particles, posttreatment is preferably performed. For example, for a porous semiconductor made of titanium oxide, posttreatment with an aqueous titanium tetrachloride solution can improve the performance of the porous semiconductor. Furthermore, the surface area of the porous semiconductor may be increased, or the defect level of the semiconductor fine particles may be lowered.

<<Formation of Porous Insulating Layer>>

The porous insulating layer 201 is then formed on the photoelectric conversion layer 23. The porous insulating layer 201 can be formed by the same method as in the porous semiconductor layer. More specifically, fine particles made of an insulating material, such as niobium oxide, dispersed in a solvent are mixed with a high-molecular compound, such as ethylcellulose or poly(ethylene glycol) (PEG), to prepare a paste. The paste thus prepared is applied to the photoelectric conversion layer 23 and is subjected to at least one of drying and baking. This can form the porous insulating layer 201 on the photoelectric conversion layer 23.

(Adsorption of Photosensitizer)

A photosensitizer is then adsorbed on the porous semiconductor layer to form the photoelectric conversion layer 23. The photosensitizer may be adsorbed on the porous semiconductor layer by any method, for example, by immersing the porous semiconductor layer in a solution for dye adsorption. In order to allow the solution for dye adsorption to permeate deep into micropores in the porous semiconductor layer, the solution for dye adsorption is preferably heated.

The photosensitizer may be dissolved in any solvent that can dissolve the photosensitizer, for example, an alcohol, toluene, acetonitrile, tetrahydrofuran (THF), chloroform, or dimethylformamide. The solvent is preferably purified. Two or more solvents may be used in combination.

The dye concentration of the solution for dye adsorption depends on the type of dye, the type of solvent, and the conditions for the dye adsorption process. In order to improve the adsorption function, the dye concentration is preferably high, for example, 1×10⁻⁵ mol/L or more. In order to improve the solubility of the dye, the solution for dye adsorption may be prepared under heating.

Although the present invention will be further described in the following examples, the present invention is not limited to these examples. Unless otherwise specified, the thickness of each layer was measured with a surface texture and contour measuring instrument (trade name: Surfcom 1400A, manufactured by Tokyo Seimitsu Co., Ltd.).

### EXAMPLE 1

In the present example, a photoelectric conversion device illustrated in FIGS. 1(a) and 1(b) was manufactured. A transparent electrode substrate of 10 mm×40 mm×1.0 mm in thickness (manufactured by Nippon Sheet Glass Co., Ltd., a glass sheet with a SnO₂ film, sheet resistance: 10.5 ohms per square) was prepared. The transparent electrode substrate included a SnO₂ transparent electrically conductive layer 2 on a transparent or translucent glass substrate 1.

A commercially available titanium oxide paste (manufactured by Solaronix, trade name: D/SP) was applied to the transparent electrically conductive layer 2 of the transparent electrode substrate with a screen plate having a 5 mm×30 mm pattern and a screen printer (manufactured by Newlong Seimitsu Kogyo Co., Ltd., model number: LS-150) and was leveled off at room temperature for one hour.

The titanium oxide paste coating film was dried in an oven at 80° C. for 20 minutes. The coating film was baked in a furnace (manufactured by Denken Co., Ltd., model number: KDF P-100) at 500° C. in the air for 60 minutes. The application and baking of the titanium oxide paste were performed four times by the methods described above, thereby forming a porous semiconductor layer having a thickness of 25 μm.

A 5 mm×10 mm titanium terminal electrode 8 on a photoelectric conversion layer side was then formed with a vapor deposition apparatus on the transparent electrically conductive layer 2 at each end of the porous semiconductor layer in the longitudinal direction. The terminal electrode 8 on the photoelectric conversion layer side had a thickness of 1 μm and a sheet resistance of 1.1 ohms per square.

A dye having the formula (2) (manufactured by Solaronix, trade name: Ruthenium 620 1H3TBA) was then dissolved in a 1:1 (volume ratio) mixed solvent of acetonitrile and t-butanol such that the dye concentration was 4×10⁻⁴ mol/liter. A solution for dye adsorption was thus prepared.

The porous semiconductor layer was immersed in the solution for dye adsorption at room temperature for 100 hours. The porous semiconductor layer was then washed with ethanol and was dried at approximately 60° C. for approximately 5 minutes to allow the dye to be adsorbed on the porous semiconductor layer. Thus, a photoelectric conversion layer 3 composed of a porous semiconductor layer on which the dye was adsorbed was formed.

A supporting substrate 7 was the same as the transparent electrode substrate described above. A counter electrically conductive layer 6 made of SnO₂ was disposed on a surface of the supporting substrate 7 made of glass. A catalyst layer 5 having the same size as the photoelectric conversion layer 3 was disposed on the supporting substrate 7 on which the counter electrically conductive layer 6 had been formed. The catalyst layer 5 was disposed on top of the photoelectric conversion layer 3. A counter terminal electrode 8′ having the same shape as the terminal electrode 8 on the photoelectric conversion layer side was disposed on the supporting substrate 7 on which the counter electrically conductive layer 6 had been formed and disposed at each end of the supporting substrate 7 in the longitudinal direction outside the catalyst layer 5.

A heat seal film (manufactured by Du Pont, Himilan 1702) cut out to surround the photoelectric conversion layer 3 was placed around the photoelectric conversion layer 3. The supporting substrate 7 on which the counter electrically conductive layer 6 had been formed was placed on the heat seal film and was heated in an oven at approximately 100° C. for 10 minutes. Thus, the supporting substrate 7 was press-bonded to the transparent electrode substrate including the transparent or translucent substrate 1 and the transparent electrically conductive layer 2. This heat seal film served as a sealant 9.

A carrier transport material prepared in advance was then injected through an electrolyte solution inlet formed in the supporting substrate 7. The electrolyte solution inlet was then sealed with a UV curable resin (manufactured by ThreeBond Co., Ltd., product number: 31X-101) to complete a photoelectric conversion device (a single cell) according to the present example. A Ag paste (manufactured by Fujikura Kasei Co., Ltd., trade name: Dotite) was applied to the transparent or translucent substrate 1 of the photoelectric conversion device 10 to form a collecting electrode.

The carrier transport material contains acetonitrile as a solvent, LiI (manufactured by Aldrich, at a concentration of 0.1 mol/liter in the carrier transport material) and I₂ (manufactured by Kishida Chemical Co., Ltd., at a concentration of 0.01 mol/liter in the carrier transport material) as redox species, and t-butylpyridine (manufactured by Aldrich, at a concentration of 0.5 mol/liter in the carrier transport material) and dimethylpropylimidazole iodide (Shikoku Chemicals Corporation, at a concentration of 0.6 mol/liter in the carrier transport material) as additive agents.

### EXAMPLES 2 AND 3

Photoelectric conversion devices according to Examples 2 and 3 were manufactured in the same manner as in Example 1 except that the structure and size of the terminal electrode 8 on the photoelectric conversion layer side and the counter terminal electrode 8′ were changed. More specifically, in Example 2, the terminal electrode 8 on the photoelectric conversion layer side and the counter terminal electrode 8′ were made of a 1 mm×10 mm titanium sheet having a thickness of 2 μm (sheet resistance: 0.71 ohms per square). In Example 3, the terminal electrode 8 on the photoelectric conversion layer side and the counter terminal electrode 8′ were made of a 1 mm×10 mm titanium sheet having a thickness of 0.5 μm (sheet resistance: 2.3 ohms per square).

### COMPARATIVE EXAMPLE 1

A photoelectric conversion device according to Comparative Example 1 was manufactured in the same manner as in Example 1 except that the transparent or translucent substrate 1 and the supporting substrate 7 had a size of 10 mm×30 mm, and no terminal electrode 8 on the photoelectric conversion layer side and no counter terminal electrode 8′ were formed.

### EXAMPLE 4

In Example 4, a photoelectric conversion device illustrated in FIGS. 2(a) and 2(b) was manufactured. A transparent electrode substrate of 15 mm×40 mm×1.0 mm in thickness (manufactured by Nippon Sheet Glass Co., Ltd., a glass sheet with a SnO₂ film) was prepared. The transparent electrode substrate included a fluorine-doped SnO₂ transparent electrically conductive layer 12 on a transparent or translucent glass substrate 11.

The transparent electrically conductive layer 12 of the transparent electrode substrate was cut by laser scribing to form a scribe line 12′. A porous semiconductor layer having a thickness of 25 μm was formed on the transparent electrically conductive layer 2 by the method described in Example 1. A terminal electrode 8 on the photoelectric conversion layer side was then formed on a photoelectric conversion layer 13 side of the scribe line 12′ by the method described in Example 1.

A paste containing zirconia particles having an average particle size of 50 nm was then applied to the porous semiconductor layer with a screen plate having a 7 mm×38 mm pattern and a screen printer. The paste was baked at a temperature of 500° C. for 60 minutes to form a porous insulating layer 101, which had a flat portion having a thickness of 13 μm.

A catalyst layer 15 (Pt catalyst layer 15) having the same size as the porous semiconductor layer was formed on the porous insulating layer 101 on top of the porous semiconductor layer. A counter electrically conductive layer 16 and a counter terminal electrode 18′ were formed simultaneously on the catalyst layer 15 and in a 9 mm×36 mm region on a surrounding area of the catalyst layer 15 by the vapor deposition of titanium.

A dye was adsorbed on the porous semiconductor layer by the method described in Example 1 to form a photoelectric conversion layer 13. After that, a 11 mm×40 mm glass substrate was prepared as a supporting substrate 17. The supporting substrate 17 was press-bonded to the transparent electrode substrate including the transparent or translucent substrate 11 and the transparent electrically conductive layer 12 by the method described in Example 1, more specifically, using a heat seal film (manufactured by Du Pont, Himilan 1702). A carrier transport material was injected through an inlet formed in the supporting substrate 17 by the method described in Example 1. The inlet was sealed to complete the photoelectric conversion device according to Example 4.

### EXAMPLE 5

In Example 5, a photoelectric conversion device illustrated in FIGS. 3(a) and 3(b) was manufactured. More specifically, a photoelectric conversion device according to Example 5 was manufactured in the same manner as in Example 4 except that the porous insulating layer had a size of 7 mm×30 mm and a 7 mm×4 mm insulating layer 202 was formed at each end of the porous insulating layer. The material of the insulating layer 202 was a glass paste.

### COMPARATIVE EXAMPLE 2

A photoelectric conversion device according to Comparative Example 2 was manufactured in the same manner as in Example 4 except that the counter electrically conductive layer 16 formed on the porous insulating layer 101 had a size of 9 mm×30 mm and no counter terminal electrode was formed.

### EXAMPLE 6

In Example 6, a photoelectric conversion device module illustrated in FIG. 7 was manufactured. A cross-sectional structure taken along the line D-D in FIG. 7 was the same as the cross-sectional structure illustrated in FIG. 2(b). First, a transparent electrode substrate 50 mm in length×37 mm in width×1.0 mm in thickness (manufactured by Nippon Sheet Glass Co., Ltd., a glass sheet with a SnO₂ film) was prepared. The transparent electrode substrate included a SnO₂ transparent electrically conductive layer 32 on a transparent or translucent glass substrate 31.

A 9 mm×35 mm terminal electrode on the photoelectric conversion layer side was formed in a place 1 mm away from each end of the transparent electrode substrate.

The transparent electrically conductive layer 32 and the terminal electrode on the photoelectric conversion layer side were cut by laser scribing to form a scribe line 32′ having a width of 60 μm in the longitudinal direction. The scribe line 32′ was spaced 9.5 mm from the left end, and additional three scribe lines 32′ were formed at intervals of 7 mm. Thus, four scribe lines 32′ were formed.

A porous semiconductor layer 25 μm, 5 mm in width, and 30 mm in length was formed by the method described in Example 1 such that the center of the porous semiconductor layer was spaced 6.9 mm from the left end of the transparent or translucent substrate 31. Additional three porous semiconductor layers having the same size were formed at intervals of 7 mm.

A porous insulating layer 301 was formed on each of the porous semiconductor layers by the method described in Example 4. The center of the porous insulating layer 301 was spaced 6.9 mm from the left end of the transparent or translucent substrate 31. The porous insulating layer 301 had a width of 5.6 mm and a length of 46 mm. Additional three porous insulating layers 301 having the same size were formed at intervals of 7 mm from the center of the leftmost porous insulating layer 301.

A Pt catalyst layer 35 was then formed on each of the porous insulating layers 301 in the same manner as in Example 1. The catalyst layer 35 was disposed on top of each of the porous semiconductor layers and had the same size as the porous semiconductor layers. A counter electrically conductive layer 36 and a counter terminal electrode were formed by the method described in Example 1. The center of the counter electrically conductive layer 36 was spaced 7.2 mm from the left end of the transparent or translucent substrate 31. The counter electrically conductive layer 36 had a width of 5.6 mm and a length of 44 mm. Additional three counter electrically conductive layers 36 having the same size were formed at intervals of 7 mm from the center of the leftmost porous insulating layer 301.

The four porous semiconductor layers were immersed in the solution for dye adsorption used in Example 1 at room temperature for 120 hours, thereby allowing the dye to be adsorbed on the porous semiconductor layers. A UV curable resin (31X-101 manufactured by ThreeBond Co., Ltd.) was then applied between adjacent photoelectric conversion layers 33 and around the transparent or translucent substrate 31 with a dispenser (Ultrasaver manufactured by EFD). A supporting substrate 37, which was a glass substrate 60 mm in length×30 mm in width, was placed on it and was irradiated with ultraviolet light of an ultraviolet lamp (Novacure manufactured by EFD). Thus, a sealant 39 made of the UV curable resin was formed.

A carrier transport material was then injected through an inlet formed in the supporting substrate 37 by the method described in Example 1, and the inlet was sealed with a UV curable resin. Thus, a photoelectric conversion device module according to the present example was completed. A Ag paste (manufactured by Fujikura Kasei Co., Ltd., trade name: Dotite) was applied to the transparent or translucent substrate 31 of the photoelectric conversion device module to form a collecting electrode 41.

### EXAMPLE 7

In Example 7, a photoelectric conversion device module was manufactured in the same manner as in Example 6 except that the cross-sectional structure taken along the line D-D in FIG. 7 was the structure illustrated in FIG. 3(b).

First, a terminal electrode on the photoelectric conversion layer side was formed by the method described in Example 6. A glass paste (manufactured by Noritake Co., Ltd., trade name: glass paste) was then applied to the terminal electrode on the photoelectric conversion layer side with a screen printing plate having the same shape as the screen printing plate used in the formation of the terminal electrode on the photoelectric conversion layer side and with a screen printer (manufactured by Newlong Seimitsu Kogyo Co., Ltd., model number: LS-34TVA). The glass paste coating film was dried at 100° C. for 15 minutes and was baked in a furnace at 500° C. for 60 minutes to form an insulating member (corresponding to the insulating layer 202 in FIG. 3(b)). After that, a photoelectric conversion device module according to the present example was manufactured in the same manner as in Example 6 except that the porous insulating layer had a width of 5.6 mm and a length of 30 mm.

### COMPARATIVE EXAMPLE 3

A photoelectric conversion device module according to Comparative Example 3 was manufactured in the same manner as in Example 6 except that no terminal electrode on the photoelectric conversion layer side was formed, the counter electrically conductive layer had a size of 5.6 mm×30 mm, and no counter terminal electrode was formed.

<Solar Battery Characteristics of Photoelectric Conversion Device according to Examples 1 to 5 and Comparative Examples 1 and 2>

The solar battery characteristics of the photoelectric conversion devices according to Examples 1 to 5 and Comparative Examples 1 and 2 were examined by irradiating them with light at an intensity of 1 kW/m² (AM1.5 solar simulator). The following Table 1 shows the measurement results of short-circuit current Jsc (mA/cm²), open-circuit voltage Voc (V), fill factor (FF), and photoelectric conversion efficiency (%).

<Solar Battery Characteristics of Photoelectric Conversion Device Modules according to Examples 6 and 7 and Comparative Example 3>

The solar battery characteristics of the dye-sensitized solar cell modules according to Examples 6 and 7 were examined in the same manner as described above. Table 1 shows the results.

TABLE 1

| | | | | Conversion |
|---|---|---|---|---|
| | Jsc | | | efficiency |
| | (mA/cm²) | Voc (V) | FF | (%) |
| Example 1 | 18.56 | 0.701 | 0.681 | 8.86 |
| Example 2 | 18.53 | 0.702 | 0.679 | 8.83 |
| Example 3 | 18.49 | 0.699 | 0.674 | 8.71 |
| Comparative | 18.5 | 0.70 | 0.66 | 8.55 |
| example 1 | | | | |
| Example 4 | 17.21 | 0.71 | 0.671 | 8.2 |
| Example 5 | 17.23 | 0.709 | 0.681 | 8.32 |
| Comparative | 17.2 | 0.709 | 0.652 | 7.95 |
| example 2 | | | | |
| Example 6 | 4.15 | 2.831 | 0.665 | 7.81 |
| Example 7 | 4.17 | 2.821 | 0.673 | 7.92 |
| Comparative | 4.16 | 2.819 | 0.648 | 7.6 |
| example 3 | | | | |

In Table 1, comparing the photoelectric conversion devices according to Examples 1 to 3 with the photoelectric conversion device according to Comparative Example 1, the formation of a terminal electrode on the photoelectric conversion layer side and a counter terminal electrode can improve the fill factor and consequently improve the solar battery characteristics.

Comparison of the photoelectric conversion devices according to Examples 4 and 5 with the photoelectric conversion device according to Comparative Example 2 leads to the same results as in the comparison of Examples 1 to 3 with Comparative Example 1. Comparison of the dye-sensitized solar cell modules according to Examples 6 and 7 with the dye-sensitized solar cell module according to Comparative Example 3 leads to the same results as in the comparison of Examples 1 to 3 with Comparative Example 1.

Although the embodiments and examples of the present invention have been described above, appropriate combinations of the constituents of the embodiments and examples were also originally envisaged.

It is to be understood that the embodiments and examples described above are illustrated by way of example and not by way of limitation in all respects. The scope of the present invention is defined by the appended claims rather than by the description preceding them. All changes that fall within the scope of the claims and the equivalents thereof are therefore intended to be embraced by the claims.

### REFERENCE SIGNS LIST

1, 11, 21, 31 transparent or translucent substrate, 2, 12, 22, 32 transparent electrically conductive layer, 3, 13, 23, 33 photoelectric conversion layer, 4, 14 carrier transport material, 5, 15, 25, 35 catalyst layer, 6, 16, 26, 36 counter electrically conductive layer, 7, 17, 27, 37 supporting substrate, 8, 18, 28 terminal electrode on photoelectric conversion layer side, 8′, 18′, 28′ counter terminal electrode, 9, 19, 29, 39 sealant, 10, 20, 30 photoelectric conversion device, 12′, 32′ scribe line, 41 collecting electrode, 101 porous insulating layer, 103 collecting electrode, 104 photoelectric conversion layer, 201 porous insulating layer, 202 insulating layer, 203 photoelectric conversion layer, 204 collecting electrode, 301 porous insulating layer.

1. A photoelectric conversion device that includes a transparent or translucent substrate and a supporting substrate both fixed in place with a sealant, the photoelectric conversion device further comprising:
a transparent electrically conductive layer disposed on the transparent or translucent substrate;
a photoelectric conversion layer, disposed on the transparent electrically conductive layer;
a counter electrically conductive layer in contact with or separated from the supporting substrate;
a terminal electrode on the photoelectric conversion layer side electrically connected to the transparent electrically conductive layer; and
a counter terminal electrode electrically connected to the counter electrically conductive layer,
wherein the transparent electrically conductive layer, the photoelectric conversion layer, and the counter electrically conductive layer contain a carrier transport material.

2. The photoelectric conversion device according to claim 1, wherein the terminal electrode on the photoelectric conversion layer side has a sheet resistance equal to or lower than the sheet resistance of the transparent electrically conductive layer.

3. The photoelectric conversion device according to claim 1, wherein the counter terminal electrode has a sheet resistance equal to or lower than the sheet resistance of the counter electrically conductive layer

4. The photoelectric conversion device according to claim 1, wherein at least part of the terminal electrode on the photoelectric conversion layer side or at least part of the counter terminal electrode is in contact with a porous insulating layer disposed on the photoelectric conversion layer.

5. The photoelectric conversion device according to claim 1, further comprising an insulating layer between the terminal electrode on the photoelectric conversion layer side and the counter terminal electrode.

6. The photoelectric conversion device according to claim 1, wherein the photoelectric conversion layer has a width of 6 mm or less.

7. The photoelectric conversion device according to claim 1, wherein the photoelectric conversion layer has a length of 5 cm or less.

8. The photoelectric conversion device according to claim 1, wherein the terminal electrode on the photoelectric conversion layer side or the counter terminal electrode contains at least one metallic material selected from titanium, nickel, tungsten, and tantalum.

9. A photoelectric conversion device module, comprising two or more photoelectric conversion devices electrically connected in series, wherein at least one of the photoelectric conversion devices is the photoelectric conversion device according to claim 1.

10. A photoelectric conversion device module, comprising the photoelectric conversion devices according to claim 1 connected in series.
